(19) United States
(12) Patent Application Publication
(10) Pub. No.: US 2008/0070326 A1
(43) Pub. Date: Mar. 20, 2008

(54) METHOD FOR MANUFACTURING SEMICONDUCTOR DEVICE

(75) Inventor: Kenkichi SUEZAWA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi, Kanagawa (JP)

(21) Appl. No.: 11/857,209

(22) Filed: Sep. 18, 2007

Related U.S. Application Data
(63) Continuation of application No. PCT/JP2005/005020, filed on Mar. 18, 2005.

(51) Int. Cl. H01L 21/02

(52) U.S. Cl. 438/3; 257/E21.009

(57) ABSTRACT

It is an aspect of the embodiments discussed herein to provide a method manufacturing a semiconductor device, including forming a bottom electrode film above a semiconductor substrate, forming an insulating film on the bottom electrode film, forming a top electrode on the insulating film, forming a capacitor insulating film by patterning the insulating film, and removing a substance adhered to at least one selected from a group consisting of the top electrode, the capacitor insulating film, the bottom electrode film by an etchback.

### TECHNICAL FIELD

The embodiments discussed herein are directed to a method for manufacturing a semiconductor device suitable for a nonvolatile memory including a ferroelectric capacitor.

### BACKGROUND ART

Conventionally, a Pt film is mainly used for a bottom electrode of a ferroelectric capacitor. Pt is a noble metal having lower reactivity under a normal temperature. Therefore, when patterning the Pt film, an etching with an intense sputtering component is frequently relied on. However, when the etching as described above is performed, there is sometimes caused a case where particles and the like scattered by the etching adhere to a side portion of a ferroelectric film and the like to increase leak current of the ferroelectric capacitor.

Therefore, in an aim to prevent such an adhesion, a method in which the bottom electrode is patterned into a taper shape while a resist pattern used as a mask is caused to retreat, a method in which reactivity under a high temperature is increased to perform a pattering, or so forth is sometimes adopted.

However, there is still a case where the adhesion cannot be prevented sufficiently even with the methods.

[Patent document 1] Japanese Patent Application Laid-Open No. Hei 10-233489

[Patent document 2] Japanese Patent Application Laid-Open No. 2003-318371

[Patent document 3] Japanese Patent Application Laid-Open No. 2000-340767

### SUMMARY

It is an aspect of the embodiments discussed herein to provide a method for manufacturing a semiconductor device, including forming a bottom electrode film above a semiconductor substrate, forming an insulating film on the bottom electrode film, forming a top electrode on the insulating film, forming a capacitor insulating film by patterning the insulating film, and removing a substance adhered to at least one selected from a group consisting of the top electrode, the capacitor insulating film, the bottom electrode film by an etchback.

### BRIEF DESCRIPTION OF THE DRAWINGS

FIG. 1 is a circuit diagram showing a configuration of a memory cell array of a ferroelectric memory (semiconductor device) manufactured by a method according to an embodiment;

FIG. 2A is a sectional view showing a method for manufacturing a ferroelectric memory according to an embodiment in the order of process.

FIG. 2B is continued from FIG. 2A and is a sectional view showing the method for manufacturing a ferroelectric memory according to the embodiment in the order of the process;

FIG. 2C is continued from FIG. 2B and is a sectional view showing the method for manufacturing a ferroelectric memory according to the embodiment in the order of the process;

FIG. 2D is continued from FIG. 2C and is a sectional view showing the method for manufacturing a ferroelectric memory according to the embodiment of in the order of the process;

FIG. 2E is continued from FIG. 2D and is a sectional view showing the method for manufacturing a ferroelectric memory according to the embodiment in the order of the process;

FIG. 2F is continued from FIG. 2E and is a sectional view showing the method for manufacturing a ferroelectric memory according to the embodiment in the order of the process;

FIG. 2G is continued from FIG. 2F and is a sectional view showing the method for manufacturing a ferroelectric memory according to the embodiment in the order of the process;

FIG. 2H is continued from FIG. 2G and is a sectional view showing the method for manufacturing a ferroelectric memory according to the embodiment in the order of the process;

FIG. 3 is a graph showing a leak current between a top electrode and a bottom electrode;

FIG. 4 is a graph showing a leak current between adjacent two top electrodes;

FIG. 5 is an electron micrograph showing a section of a ferroelectric capacitor manufactured in accordance with a conventional method;

FIG. 6A is a sectional view showing a method for manufacturing a ferroelectric memory according to another embodiment; and

FIG. 6B is continued from FIG. 6A and is a sectional view showing the method for manufacturing a ferroelectric memory in the order of process.

### DETAILED DESCRIPTION OF THE PREFERRED EMBODIMENTS

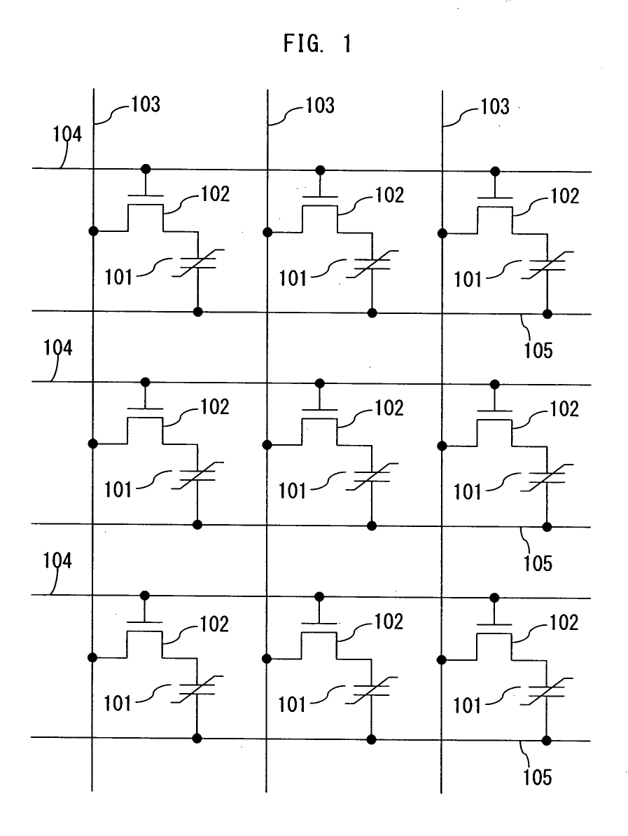

Hereinafter, embodiments will be described concretely with reference to the attached drawings. FIG. 1 is a circuit diagram showing a configuration of a memory cell array of a ferroelectric memory (semiconductor device) manufactured by a method according to an embodiment.

The memory cell array includes a plurality of bit lines 103 extending in a single direction and a plurality of word lines 104 and plate lines 105 extending orthogonal to the extending direction of the bit lines 103. Further, a plurality of memory cells of the ferroelectric memory according to the present embodiment are arranged in an array and in conformity with a lattice formed by these bit lines 103, word lines 104 and plate lines 105. Each memory cell is provided with a ferroelectric capacitor (memory section) 101 and a MOS transistor (switching section) 102.

A gate of the MOS transistor 102 is connected to the word line 104. Meanwhile, one of a source and a drain of the MOS transistor 102 are connected to the bit line 103 and the other of the source and the drain of the MOS transistor 102 are connected to one electrode of the ferroelectric capacitor 101. The other electrode of the ferroelectric capacitor 101 is connected to the plate line 105. Note that the respective word lines 104 and the plate lines 105 are shared by the plurality of MOS transistors 102 aligned in the same direction as the extending direction of the word lines 104 and the plate lines 105. Similarly, the respective bit lines 103 are shared by the plurality of MOS transistors 102 aligned in the same direction as the extending direction of the bit lines 103. The extending direction of the word lines 104 and the plate lines 105, and the extending direction of the bit lines 103 are sometimes called a row direction and a column direction, respectively. Note that the arrangement of the bit lines 103, the word lines 104 and the plate lines 105 is not limited to the above.

In the memory cell array of the ferroelectric memory thus configured, data is stored in accordance with a polarization state of a ferroelectric film provided in the ferroelectric capacitor 101.

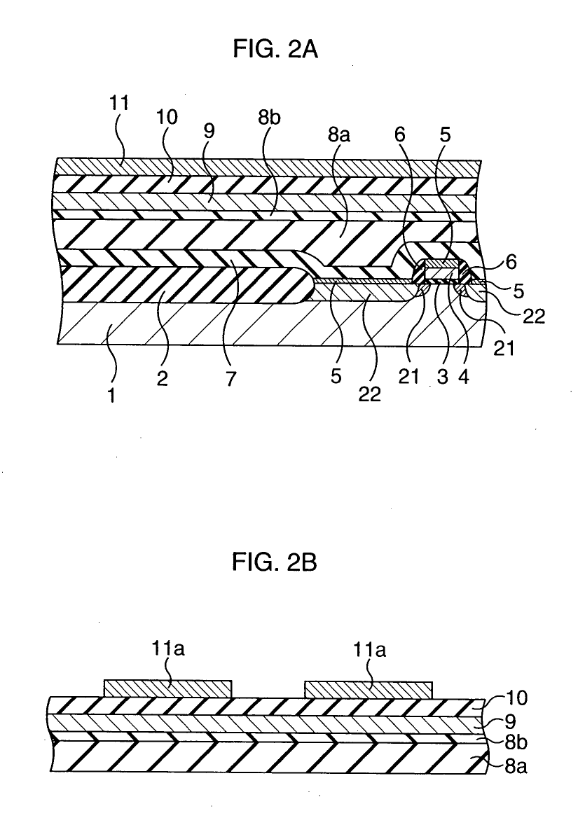

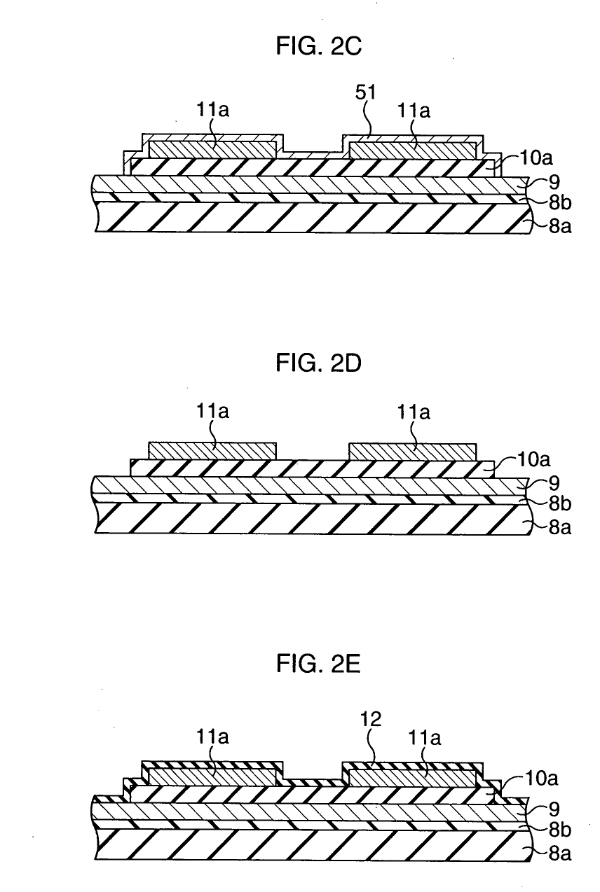

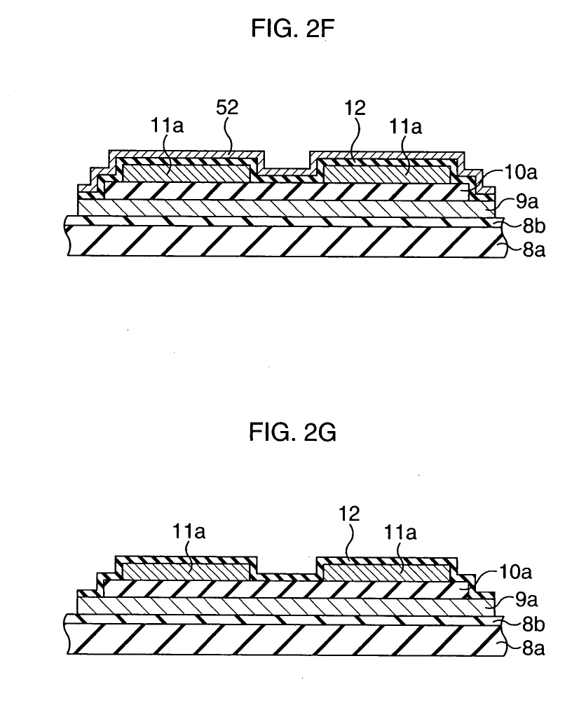

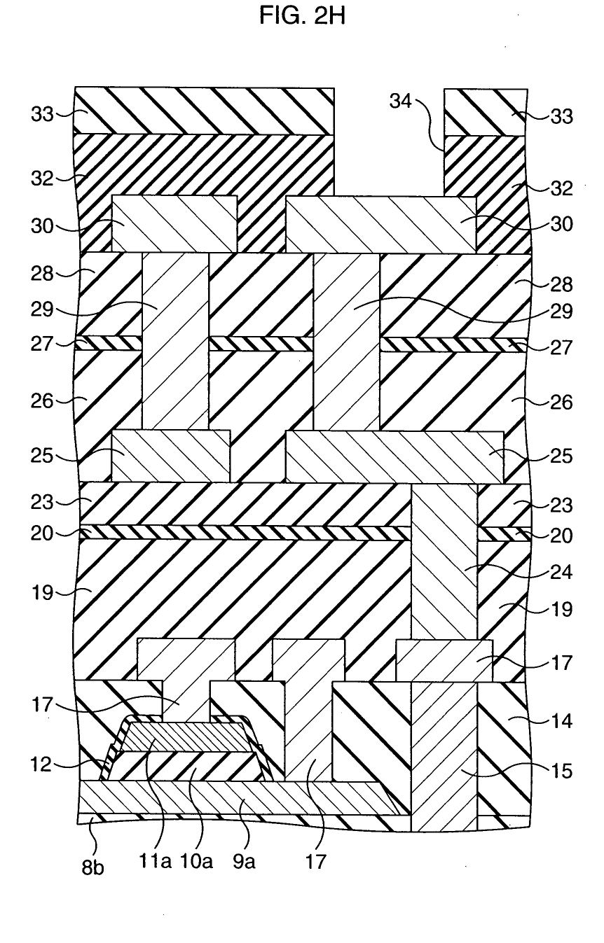

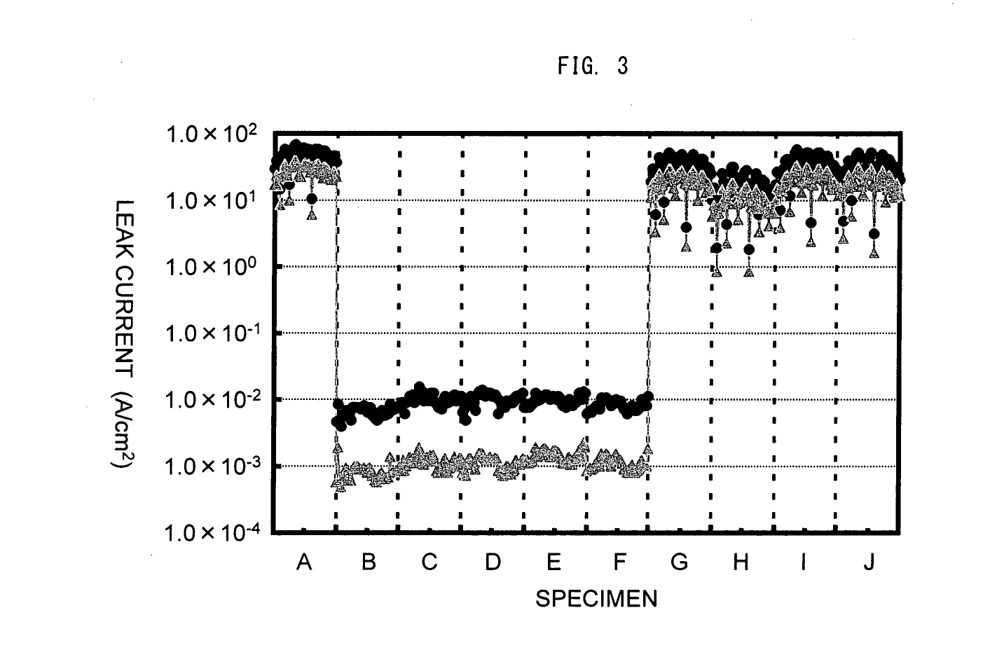

Next, the description will be given of an embodiment. FIG. 2A to FIG. 2H are sectional views showing a method for manufacturing a ferroelectric memory (semiconductor device) according to the embodiment.

In the present embodiment, first, as shown in FIG. 2A, an element isolation insulating film 2 defining an element active region is formed on the surface of a semiconductor substrate 1 such as an Si substrate, for example, by a LOCOS (Local Oxidation of Silicon) process. Subsequently, in the element active region defined by the element isolation insulating film 2, a transistor (MOSFET) with a gate insulating film 3, a gate electrode 4, a silicide layer 5, a sidewall 6, and source/drain diffusion layers composed of a low-concentration diffusion layer 21 and a high-concentration diffusion layer 22 is formed. The transistor corresponds to the MOS transistor 102 in FIG. 1. As the gate insulating film 3, for example, a SiO₂ film having a thickness of about 100 nm is formed by thermal oxidation. Subsequently, a silicon oxynitride film 7 is formed all over the surface so as to cover the MOSFET, and further a silicon oxide film 8a is formed all over the surface. The silicon oxynitride film 7 is formed to prevent a hydrogen degradation of the gate insulating film 3 and so on when the silicon oxide film 8a is formed. As the silicon oxide film 8a, for example, a TEOS (tetraethylorthosilicate) film having a thickness of about 700 nm is formed.

Then, a degassing is performed to the silicon oxide film 8a by an annealing treatment in an N₂ atmosphere at a temperature of 650° C. for 30 minutes. Subsequently, as a bottom electrode adhesive layer, for example, an Al₂O₃ film 8b having a thickness of about 20 nm is formed on the silicon oxide film 8a by sputtering. A bottom electrode film 9 is formed on the Al₂O₃ film 8b. As the bottom electrode film 9, for example, an Ir film or a Pt film having a thickness of about 150 nm is formed by sputtering.

Subsequently, as also shown in FIG. 2A, a ferroelectric film 10 in an amorphous state is formed on the bottom electrode film 9. As the ferroelectric film 10, for example, a PZT film having a thickness of about 100 nm to 200 nm is formed by RF sputtering using a PZT (Pb (Zr, Ti) O₃) target. Thereafter, a thermal treatment (RTA: Rapid Thermal Annealing) at a temperature of 650° C. or below is performed in an atmosphere containing Ar and O₂, and further, another RTA at 750° C. is performed in an oxygen atmosphere. As a result, the ferroelectric film 10 is completely crystallized, and at the same time, the bottom electrode film 9 is densified to suppress interdiffusion in the vicinity of the interface between the bottom electrode film 9 and the ferroelectric film 10.

Then, as also shown in FIG. 2A, a top electrode film 11 is formed on the ferroelectric film 10. In forming the top electrode film 11, for example, an iridium oxide film having a thickness of about 200 nm to 300 nm is formed by sputtering.

Thereafter, a top electrode 11a is formed by patterning the top electrode film 11, as shown in FIG. 2B. Subsequently, a thermal treatment is performed in an atmosphere containing oxygen to mitigate damage and so on caused by the patterning.

Subsequently, a patterning with over etching is performed to the ferroelectric film 10 to form a capacitor insulating film 10a, as shown in FIG. 2C. At this time, by the over etching, the surface layer portion of the bottom electrode film 9 is etched and the particles and the like scattered therefrom adhere to the side portion of the capacitor insulating film 10a and so on to thereby form a layer 51 with electric conductivity, as shown in FIG. 2C. Note that the particles and the like also adhere to the surface of a resist mask used in the patterning, and remain on the top electrodes 11a and so on even after the resist mask is removed.

Then, by performing an etchback all over the surface, the layer 51 is removed, as shown in FIG. 2D. Note that the etchback is performed at a lower power and in a short period of time.

After that, as shown in FIG. 2E, as a protective film, an Al₂O₃ film 12 is formed all over the surface by sputtering. Subsequently, an oxygen annealing is performed to mitigate damage by the sputtering. With the protective film (Al₂O₃ film 12), hydrogen is prevented from entering into the ferroelectric capacitor from outside.

Thereafter, as shown in FIG. 2F, the Al₂O₃ film 12 and the bottom electrode film 9 are patterned to form a bottom electrode 9a. The ferroelectric capacitor including the bottom electrode 9a, the capacitor insulating film 10a, and the top electrode 11a corresponds to the ferroelectric capacitor 101 in FIG. 1. At this time, particles scattered from the bottom electrode film 9 adhere to a circumference of the Al₂O₃ film 12 and so on to form a layer 52 with electric conductivity, as shown in FIG. 2F.

Subsequently, by performing an etchback all over the surface, the layer 52 is removed, as shown in FIG. 2G. Note that the etchback is performed also at the lower power and in the short period of time.

Then, as shown in FIG. 2H, an interlayer insulating film 14 is formed all over the surface by a high-density plasma process. The thickness of the interlayer insulating film 14 is set, for example, to 1.5 μm. After that, the interlayer insulating film 14 is planarized by a CMP (chemical mechanical polishing) process. Subsequently, a plasma process using N₂O gas is performed. As a result, the surface layer portion of the interlayer insulating film 14 is slightly nitrided, where moisture is difficult to enter thereinto. Note that the plasma process is effective when a gas containing at least one of N (nitrogen) or O (oxygen). Subsequently, a hole reaching to the silicide layer 5 on the high-concentration diffusion layer 22 is formed in the interlayer insulating film 14, the Al₂O₃ film 8b, the silicon oxide film 8a, and the silicon oxynitride film 7. After that, a Ti film and a TiN film are formed sequentially in the hole by sputtering to form a barrier metal film (not shown). Thereafter, further, a W (tungsten) film is buried in the hole by a CVD (chemical vapor deposition) process, and the W film is planarized by a CMP process to form a W (tungsten) plug 15.

Subsequently, as shown also in FIG. 2H, a contact hole reaching to the top electrodes 11a and a contact hole reaching to the bottom electrode 9a are formed in the interlayer insulating film 14 and the like. Then, an Al film is formed, while a part of the surface of the top electrode 11a, a part of the surface of the bottom electrode 9a and the surface of the W plug 15 are exposed, and the Al film is patterned to form an Al wiring 17. At this time, for example, the W plug 15 and the top electrode 11a are connected to each other by a part of the Al wiring 17.

Then, as shown also in FIG. 2H, a high-density plasma oxide film 19 is formed all over the surface and the surface is planarized. Subsequently, on the high-density plasma oxide film 19, an Al₂O₃ film 20 is formed as a protective film preventing hydrogen and moisture from penetrating thereinto. Further, on the Al₂O₃ film 20, a high-density plasma oxide film 23 is formed. Subsequently, a via hole reaching to the Al wiring 17 is formed in the high-density plasma oxide film 23, the Al₂O₃ film 20, and the high-density plasma oxide film 19, and a W (tungsten) plug 24 is buried in the hole. Then, a wiring 25, a high-density plasma film 26, an Al₂O₃ film 27, a high-density plasma film 28, a W (tungsten) plug 29, an Al wiring 30, a TEOS oxide film 32, a pad silicon oxide film 33, and a pad opening 34 are formed. Such a part of the Al wiring 30 exposing from the pad opening 34 is used as a pad.

As described above, a ferroelectric memory including the ferroelectric capacitor is completed.

According to the present embodiment as described above, the layers 51 and 52 with electric conductivity are surely removed by etchback, so that the leak caused by these layers can be suppressed.

Note that, when the layers 51 and 52 with electric conductivity are removed, a plasma etching is preferably performed, and as an etching gas at that time, for example, a mixed gas of Cl₂ and Ar is usable. Further, an etching power is preferably set to 400 W or below and the time of treatment is preferably 1 second to 5 seconds (for example, 3 seconds). In particular, when a film composed of a ferroelectric substance is used as a capacitor insulating film, an etching at a normal temperature is preferably performed.

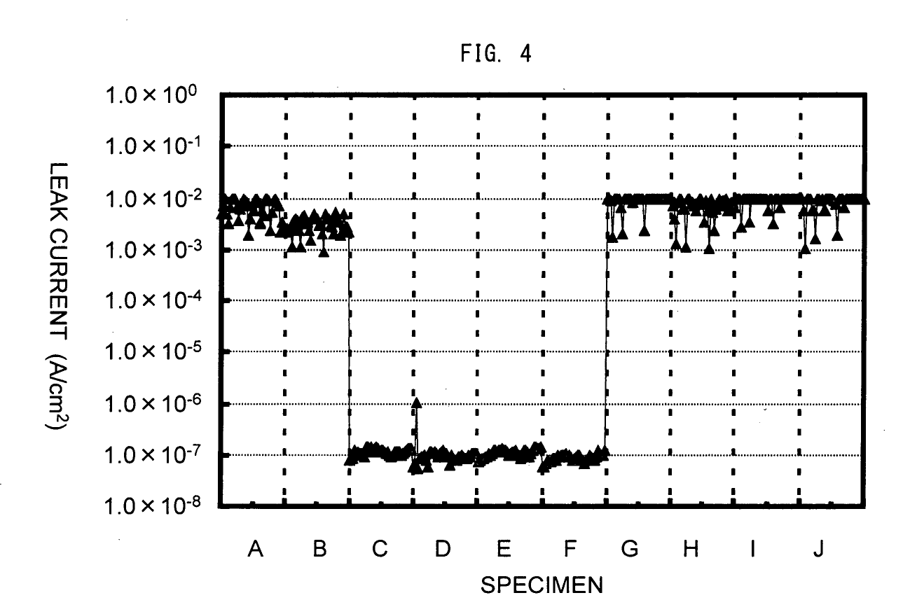

The present inventor actually measured the leak current, and the results shown in FIG. 3 and FIG. 4 were obtained. FIG. 3 shows a leak current between a top electrode and a bottom electrode, and FIG. 4 shows a leak current between adjacent two top electrodes. Note that, specimens C, D E and F in FIG. 3 and FIG. 4 are those manufactured in accordance with the above-described embodiment, and specimens A, B, G, H, I and J are those manufactured without removing the layers with electric conductivity by etchback. Note that, in FIG. 3, two types of plots (● and ▴) are presented, which show measurement results made under different voltage applications.

As shown in FIG. 3 and FIG. 4, in the case of the specimens C, D, E, and F, in which the layers with electric conductivity are removed by etchback, the leak current downs by approximately 4 digits to 5 digits compared with that of the specimens A, B, G, H, I, and J. Further, along therewith, the specimens C, D, E and F exhibits a yield of approximately 90%, while the specimens A, B, G, H, I, and J exhibit a yield of 0 (zero) %.

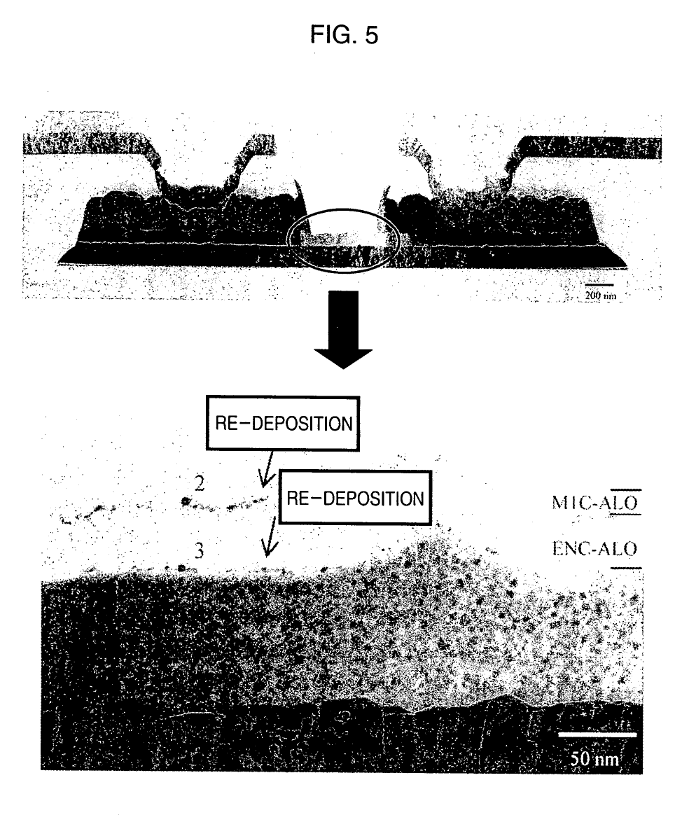

FIG. 5 is an electron micrograph showing a section of a ferroelectric capacitor manufactured in accordance with a conventional method. In the manufacturing of the ferroelectric capacitor, after patterning the ferroelectric film, a chemical treatment using an acid, a jet scrubbing and a supersonic cleaning were performed. The etchback as in the above embodiment was not performed. Therefore, as shown in FIG. 5, between a capacitor insulating film and an Al₂O₃ film (ENC-ALO), a layer of re-deposition (adherent adhered again) which generated when the ferroelectric film was patterned remained. In other words, a layer with electric conductivity remained between the adjacent two top electrodes. Also, on the Al₂O₃ film (ENC-AlO), a layer of re-deposition (adherent adhered again) which generated when the bottom electrode film was patterned remained. In the semiconductor device including this ferroelectric capacitor, affected by these conductive layers, the leak between the top electrodes was increased to exhibit an extremely low yield.

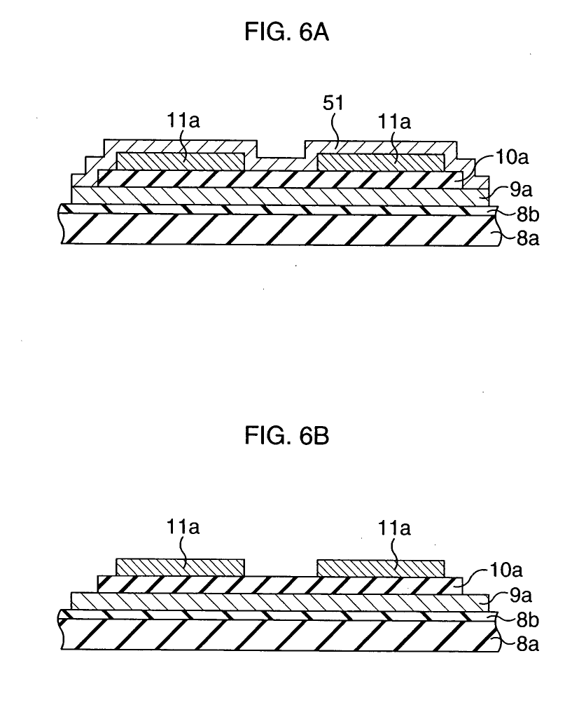

Note that, in the above-described embodiment, the protective film (Al₂O₃ film 12) is formed after patterning the ferroelectric film 10, whereas the film is not necessarily formed. In that case, after the ferroelectric film 10 (see FIG. 2C) is patterned, the patterning of the bottom electrode film 9 is performed straightway. Therefore, the thickness of the layer 51 with electric conductivity becomes higher by being affected by the particles scattered from the bottom electrode film 9, as shown in FIG. 6A.

Then, an etchback is performed all over the surface to remove the layer 51, as shown in FIG. 6B. Note that the etchback is performed also at the lower power and in the short period of time. After that, processes similar to those of the above-described embodiment are performed so as to complete the ferroelectric memory including the ferroelectric capacitor.

Note that, after the bottom electrode is formed, a protective film, such as an Al₂O₃ film, covering all over the ferroelectric capacitor may be formed.

Further, as a ferroelectric film, a PZT (PbZr₁₋ₓTiₓO₃) film, a compound film having a perovskite structure such as a PZT film added with an extremely small amount of La, Ca, Sr, Si or the like, a (SrBi₂TaₓNb₁₋ₓO₉) film, or a compound film having a Bi-layer structure such as a Bi₄Ti₂O₁₂ film may be used. Furthermore, a formation method of a ferroelectric film is not specifically limited, and the ferroelectric film may be formed by a sol-gel method, sputtering, MOCVD, and so forth.

Note that, in Patent document 1, there is presented a description that a plasma process is performed to a top electrode film and a ferroelectric film before patterning. However, even with the process being performed, the layer with electric conductivity cannot be removed.

Moreover, in Patent document 2, there is described a method that prevents scattered substances from adhering by etching a ferroelectric film into a taper shape. However, even with this method, the adherent cannot be prevented sufficiently, requiring them to be removed later.

Furthermore, in Patent document 3, there is described a method of suppressing the leak current by forming a ferroelectric film after planarizing the surface of the bottom electrode film. However, even with this method being adopted, the leak accompanied by existence of the layer with electric conductivity cannot be suppressed.

### INDUSTRIAL APPLICABILITY

As described in detail, according to the embodiment, the etchback is performed to a substance generated when a ferroelectric film is etched, allowing the substance to be removed appropriately. Accordingly, the leak caused by the substance can be suppressed.

What is claimed is:

1. A method for manufacturing a semiconductor device, comprising:
forming a bottom electrode film above a semiconductor substrate;
forming an insulating film on said bottom electrode film;
forming a top electrode on said insulating film;
forming a capacitor insulating film by patterning said insulating film; and
removing a substance adhered to at least one selected from a group consisting of said top electrode, said capacitor insulating film, said the bottom electrode film by an etchback.

2. The method for manufacturing a semiconductor device according to claim 1, further comprising forming a bottom electrode by patterning said bottom electrode film, after said removing said substance.

3. The method for manufacturing a semiconductor device according to claim 2, further comprising removing a substance adhered to at least one selected from a group consisting of said top electrode, said capacitor insulating film and said bottom electrode when said bottom electrode is formed by an etchback, after said forming said bottom electrode.

4. The method for manufacturing a semiconductor device according to claim 1, further comprising forming a bottom electrode by patterning said bottom electrode film, before said removing said substance.

5. The method for manufacturing a semiconductor device according to claim 4, wherein said substance adhered to at least one selected from a group consisting of said top electrode, said capacitor insulating film and said bottom electrode when said bottom electrode is formed is also removed at the same time of removing said substance adhered when said capacitor insulating film is formed.

6. The method for manufacturing a semiconductor device according to claim 1, wherein said bottom electrode contains Ir (iridium) or Pt (platinum).

7. The method for manufacturing a semiconductor device according to claim 1, wherein a ferroelectric film is formed as said insulating film.

8. The method for manufacturing a semiconductor device according to claim 7, wherein a compound film having a perovskite structure or a Bi-layer structure is formed as said ferroelectric film.

9. The method for manufacturing a semiconductor device according to claim 7, wherein an etching at a normal temperature is performed to said substance in said removing said substance.

10. The method for manufacturing a semiconductor device according to claim 1, wherein a plasma etching is performed to said substance in said removing said substance.

11. The method for manufacturing a semiconductor device according to claim 10, wherein a mixed gas of Cl₂ and Ar is used as an etching gas when said plasma etching is performed.

12. The method for manufacturing a semiconductor device according to claim 10, wherein a bias power when said plasma etching is performed is set to 400 W or below.

13. The method for manufacturing a semiconductor device according to claim 1, wherein a treatment time is set to 1 second to 5 seconds in said removing said substance.

14. The method for manufacturing a semiconductor device according to claim 1, wherein ferroelectric capacitors each including said top electrode and said capacitor insulating film are formed in an array.

15. The method for manufacturing a semiconductor device according to claim 2, further comprising forming a protective film covering said top electrode and said ferroelectric film between said removing said substance and said forming said bottom electrode.

16. The method for manufacturing a semiconductor device according to claim 15, wherein an alumina film is formed as said protective film.
